(19) United States
(12) Patent Application Publication
(10) Pub. No.: US 2026/0219120 A1
(43) Pub. Date: Jul. 30, 2026

(54) METHOD AND APPARATUS FOR PROVIDING MEMBRANE PATTERN BUILT-IN DIFFERENTIAL PIEZORESISTIVE PRESSURE SENSORS

(71) Applicant: Posifa Technologies Limited, Grand Cayman (KY)

(72) Inventor: Peng Tu, Palo Alto, CA (US)

(73) Assignee: Posifa Technologies Limited, Grand Cayman (KY)

(21) Appl. No.: 19/041,874

(22) Filed: Jan. 30, 2025

(51) Int. Cl. G01L 13/02; B81B 3/00; B81C 1/00; G01L 9/00

(52) U.S. Cl. CPC G01L 13/025; B81B 3/0021; B81C 1/00531; G01L 9/0052; B81B 2201/0264; B81C 2201/0132

(57) ABSTRACT

A silicon membrane pattern buried-in differential piezoresistive pressure sensor is described. The pressure sensor comprises a silicon membrane pattern built-in silicon substrate transformed from a porous silicon pattern built-in silicon substrate, a silicon membrane taken from a portion of a silicon epitaxial layer on the surface of a porous silicon layer, a thin cavity buried under the silicon membrane is created by etching the porous silicon layer, a thin vertical channel connecting the cavity to the outside of the back side of the substrate, and a pressure sensing circuit including a Wheatstone bridge constructed in/on the silicon membrane. The shape and size of the silicon membrane are the same as etching porous silicon layer and the silicon membrane can be used for fabricating a differential piezoresistive pressure sensor with an optimized design structure which results in an excellent performance. The sensor chip can be directly mounted on a printed circuit board without an anodic bonded glass base for additional mechanical strength support.

### TECHNICAL FIELD

This invention is generally related to a MEMS piezoresitive pressure sensor and more particularly is related to a silicon membrane pattern built-in differential piezoresistive pressure sensor.

### BACKGROUND OF THE INVENTION

Pressure sensors or pressure transducers can be utilized in a wide range of sensing applications. In many cases, it is desirable to measure the pressure of a particular type of media (e.g., usually gases or liquids) such as water, fuel, oil, acids, bases, solvents, and corrosive gases. The sensed media can also include (but need not be limited to) air, nitrogen, industrial process gases, water, automotive fluids, pneumatic fluids, coolants, industrial chemicals, etc. For such applications, pressure sensors can be utilized to accurately sense the pressure of the media.

In particular, one type or configuration of pressure sensor is referred to as a differential pressure sensor. This type of sensor measures the difference between two or more pressures that are supplied as inputs. An example application for a differential pressure sensor may involve measuring the pressure drop across a furnace filter or an oil filter to determine the level of clogging. Another differential pressure sensor application may be implemented in conjunction with the Venturi effect to measure flow. In such a situation, a pressure differential can be created between two segments of a venture tube that are designed with a different aperture. The pressure difference is directly proportional to the flow rate through the Venturi tube and can be accurately measured by a differential pressure sensor.

Low differential pressure sensors are ideal for building automation applications. As urban population density increases, larger buildings are becoming increasingly commonplace, and controlling their internal environment accurately is a challenge for designers and operations staff alike. In addition, rising environmental concerns and tightening regulations have made minimizing resources used to heat and cool buildings a serious consideration. The business of building automation integrates heating, ventilation, air conditioning and refrigeration (HVACR), with control interfaces and monitoring systems—all with the help of low differential pressure sensors.

U.S. Pat. No. 8,230,745 B2 described one of the most common types of differential pressure sensors utilized in many industrial and commercial applications is a solid-state MEMS pressure sensor that utilizes silicon piezoresistive technology. A typical MEMS pressure die employs a thin silicon membrane that is stressed in response to an applied pressure. Piezoresistors are strategically located or positioned on the silicon membrane. When pressure is applied to the sensor, the diaphragm is stressed and the Piezoresistors convert this mechanical stress to an electrical signal. Typically, the Piezoresistors form a Wheatstone bridge and the differential signal is proportional to the applied pressure.

Generally, the differential pressure sensor comprises a silicon substrate, having a cavity dug and accessible from the back of the substrate and a flexible silicon membrane suspended above the cavity. Piezoresistors, connected in a Wheatstone bridge configuration, are diffused in a surface portion of the flexible diaphragm, and are contacted by metallizations, and a passivation layer, made of thermal oxide, coats the top surface of the substrate.

The flexible silicon membrane is created either using dry etching using DRIE or using wet etchants like TMAH. Wet etching using TMAH is preferred as it is a low cost and simple process compared to dry etching.

The back of the substrate is bonded to a base layer, preferably made of Pyrex™ glass by anodic bonding. An access opening traverses the base layer and the intermediate layer, and reaches the cavity.

In operation, the top side of the flexible silicon membrane is placed in communication with a first chamber containing a fluid at a first pressure, and the cavity is placed in fluid communication with a second chamber, containing a fluid at a second pressure, through the access opening. Consequently, the flexible silicon membrane is deformed as a function of the difference between the first pressure and the second pressure, and the deformation brings about an unbalancing of the Wheat stone bridge formed by the Piezoresistors. The unbalancing may be detected by appropriate sensing electronics, which derives there from the desired differential pressure measurement.

Thermal-performance instability is the most ubiquitous obstruction in the application of the piezoresistive pressure sensors.

Anodic bonding between glass and silicon wafers is widely utilized for wafer level packaging. Anodic bonding is a solid state, field-assisted, irreversible bonding technique. Bonding between silicon and Corning Pyrex 7740 glass by applying voltage, temperature and/or pressure is the most established scheme. The common parameters for the process include 400-1000V of voltage and 350-450° C. of temperature. At these higher temperatures, stress may be leading to wafer bowing, which is a striking drawback in sensor chip fabrication. The Thermal expansion coefficient of silicon is larger than that of Pyrex 7740 at the temperatures above 315° C., resulting in a residual tension in the silicon when the bonded wafer pair is cooling down to room temperature. At 400° C., the difference in the Thermal expansion coefficient between the bonded wafers can be up to about 7%, which creates a wafer deflection with the curvature in the order of tens to hundreds of microns over a 100 mm wafer. Corresponding to this, for silicon and Pyrex wafers with the same thickness, the residual stress in silicon wafer will be tensile if the bonding is carried out above 315° C., and compressive if the bonding temperature is below 315° C. Moreover, the non-uniform local contact between the wafers during bonding will cause a varied temperature distribution across the wafer and lead to significant local residual stress. Besides the difference of the thermal expansion coefficient, the Poisson's ratio may also be crucial in residual stress. The residual stress in the bonding interface will greatly affect the accuracy and zero-offset of piezoresistive sensors.

The pressure sensor described, though enabling a differential pressure measurement to be carried out, has, however, rather large dimensions, principally due to the need to create a flexible silicon membrane by etching from the back of the silicon substrate. The manufacturing process, for similar reasons, is rather complex and costly, principally due to the need to perform the bonding between the silicon substrate and the Pyrex glass. Clearly, said disadvantages are particularly evident in applications wherein features such as economy and simplicity of production are constraining design characteristics.

### SUMMARY

A general object of the present invention, therefore, is to provide a silicon membrane pattern built-in differential piezoresistive pressure sensor fabricated using a porous silicon pattern built-in silicon wafer.

A more specific object of the present invention is to simplify the fabrication process of various MEMS devices including differential piezoresistive pressure sensors, where device thinning and precise silicon structure separation/definition is needed.

A more specific object of the present invention is to allow for eliminating the cumbersome step of etching cavities from the back side of a silicon substrate in the fabrication process, and permits for pre-patterning of complex cavities systems.

A more specific object of the present invention is to use the porous silicon layer in the porous silicon pattern built-in silicon substrate to automatically stop Bosch DRIE process for creating a vertical channel to the cavity from the back side of the silicon substrate.

A more specific object of the present invention is to use a dilute KOH solution to remove the porous silicon layer without any reduce of the thickness of a silicon membrane which is created by removing the porous silicon layer.

A more specific object of the present invention is to provide a differential piezoresistive pressure sensor having a thin cavity and a thin vertical channel instead of a very large cavity that is not supported with pillars would make the wafer fragile and could lead to wafer or device layer deformation.

A more specific object of the present invention is to provide a differential piezoresistive pressure sensor without need an anodic bonding so as to remove the thermal performance instability caused by the anodic bonding.

A more specific object of the present invention is to provide a differential piezoresistive pressure sensor allowed to be packaged with a standard die attach material yielding a high performance and cost effective solution.

These and other features, advantages, benefits, and objects of the present invention will become apparent to one of ordinary skill in the art upon careful consideration of the detailed description of representative embodiments of the invention herein below and the accompanying drawings.

### BRIEF DESCRIPTION OF THE DRAWINGS

The accompanying figures, in which like reference numerals refer to identical or functionally-similar elements throughout the separate views and which are incorporated in and form a part of the specification, further illustrate the embodiments and, together with the detailed description, serve to explain the embodiments disclosed herein.

FIG. 1A illustrates the top view of a silicon membrane pattern buried-in differential piezoresistive pressure sensor and FIG. 1B illustrates the cross sectional view of the silicon membrane pattern built-in differential piezoresistive pressure sensor.

FIG. 2 illustrates the cross sectional view of a porous silicon pattern built-in silicon wafer consists of a handle silicon layer, a porous silicon patterned layer and a silicon epitaxial layer.

FIG. 3 illustrates the cross sectional view of an etched porous silicon pattern built-in silicon wafer with a cavity, a silicon membrane, and a channel.

FIG. 4 illustrates the cross sectional view of a packaged silicon membrane pattern built-in differential piezoresistive pressure sensor.

### DETAILED DESCRIPTION

Differential pressure sensors are used for many automotive, medical, industrial, consumer and building devices, which depend on accurate and stable pressure measurements in order to operate reliably. As more industries rely on differential pressure sensors to monitor and control their applications, demand for these technologies has greatly increased.

In carrying out the principles of the present invention, in accordance with an embodiment thereof, a differential pressure sensor is provided which is a greatly improvement over prior sensors.

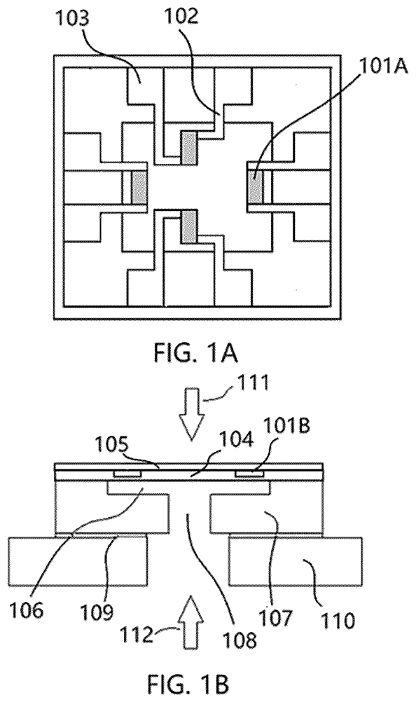

According the present invention, a silicon membrane pattern built-in differential piezoresistive pressure sensor is shown in FIG. 1A and FIG. 1B, which comprises: a silicon membrane pattern built-in silicon substrate 107, a silicon membrane 104 formed from a silicon epitaxial layer on a porous silicon layer, a thin cavity 106 buried under the silicon membrane and created by etching the porous silicon layer, a thin vertical channel 108 connecting the cavity to the outside of the bottom of the substrate, and a pressure sensing circuit including a Wheatstone bridge 101A and 101B in/on the silicon membrane, several wire bonding pads 103 and interconnection 102 on the surface of the silicon epitaxial layer which surround the silicon membrane, a printed circuit board 110 and an adhesion layer 109 used for mounting the differential pressure sensor on a printed circuit board. The pressure sensor further comprises: a passivation layer 105, an infant applied pressure 111 and a back applied pressure 112.

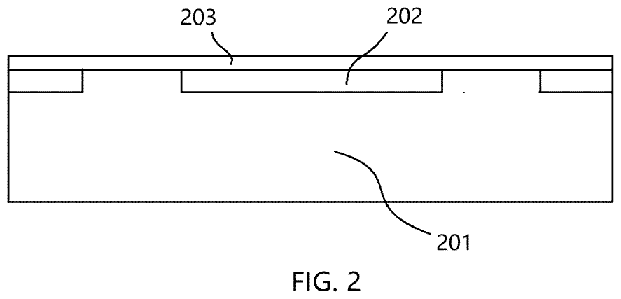

The silicon membrane pattern built-in silicon substrate 107 is transformed from a porous silicon pattern built-in silicon wafer. As shown in FIG. 2, the porous silicon pattern built-in silicon wafer consists of a handle silicon layer 201, a porous silicon pattern layer 202 and a silicon epitaxial layer 203. The silicon membrane pattern built-in silicon substrate has a lot of separated silicon membranes and the porous silicon pattern built-in silicon substrate has a lot of separated porous silicon layers.

Porous silicon is a nanostructured material prepared by electrochemical or chemical etching of crystalline silicon. It displays tuneable structural properties: a large specific surface area, large free volume, and pore sizes that can be controlled from a few nanometers to several hundreds of nanometers depending on the preparation conditions.

Porous silicon is most commonly generated by etching crystalline silicon in aqueous ethanolic hydrofluoric acid (HF) electrolytes usually using highly doped p-type, boron doped, polished (100) silicon wafers, with a resistivity of between 0.0005 and 0.001 Ohm-cm and a thickness up to 400 microns.

The epitaxial growth of a high-quality silicon layer on double-layer porous silicon by chemical vapor deposition (LPCVD) has been used for SOI wafers and solar cells. The two-step anodization process results in a double-layer porous silicon structure with a different porosity. This double-layer porous silicon structure has been found to be helpful in subsequent silicon epitaxial growth. The results show that the epitaxial silicon layer is of good crystallinity and the same orientation with the silicon substrate and the porous silicon layer.

Once silicon has been made porous, it can be removed in diluted hydroxide solutions (KOH, NaOH, NH4OH, etc) and, because of its high surface area, dissolves very quickly even at room temperature. KOH concentrations as low as 1%, at room temperature have been used to remove porous silicon layers. Care must be taken to keep the etch rate slow enough so that the reaction does not become violent, causing delicate microstructures to be destroyed by bubbles.

Porous silicon is a sponge-like structure full of pores and channels and can not be removed by Bosch Process (Deep Reactive Ion Etching). Bosch process consists of a three-step cycle: film deposition, bottom film etching, and silicon etching. In the film deposition process, a passivation film is deposited on the sidewalls and bottom surface of the pores and channels. In the bottom film etching step, the passivation film on the pores and channels bottom is selectively etched. In the silicon etching step, only the silicon at the pores and channels bottom, where the passivation film has been removed, is etched. The bottom surface of the pores and channels is very small compare with the sidewall surface of the pores and channels so the whole structure of the etched porous silicon is almost no remove at all.

Silicon micromachining technology based on porous silicon that can produce surface and buried insulators, conductors, and sacrificial layers required for silicon micromachining to fabricate micromechanical devices and sensors. Porosity and thickness of porous silicon layers for micromachining can be controlled to a relative precision better than 0.3% for porosities ranging from 20-80% and thicknesses ranging from sub-micron to hundreds of microns. The technique of using porous silicon has important implications for fabrication of silicon electromechanical devices and sensors. The high relative precision in realizing a given thickness is superior to that obtained with conventional chemical etches.

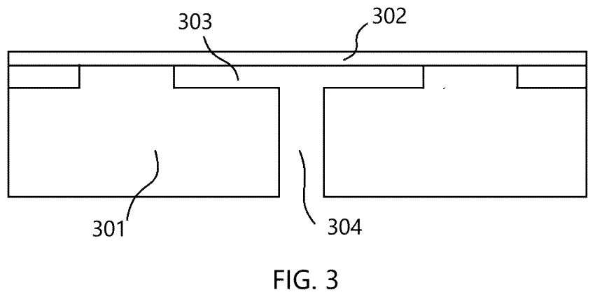

A microstructure fabricated from a porous silicon pattern buried-in silicon wafer by wet and dry etching is shown in FIG. 3. The microstructure consists of a silicon membrane 302, a buried cavity 303, a silicon support layer 301, and a vertical channel 304. The vertical channel 304 is created by Bosch RIE etching. Bosch process starts from the back surface of the silicon support layer and stops at the bottom of the porous silicon layer. The buried cavity 303 is created by dilute KOH solution etching which passes through the vertical channel.

As can be seen, the silicon membrane 302 has a shape and a size almost the same as the shape and the size of the etched porous silicon layer. The thickness of the silicon membrane also is the same as the thickness of the silicon epitaxial layer because the dilute KOH solution almost does not etch the silicon at a room temperature. The design parameters of a pressure sensor include silicon membrane size and shape and the location of piezoresistance. Such accuracy controlled silicon membrane structure benefits the design of a differential pressure sensor with a good sensitivity and linearity.

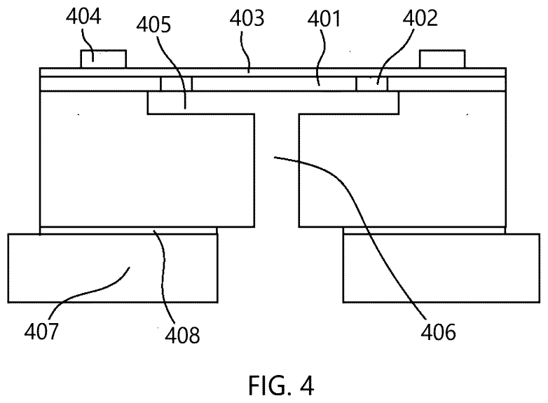

A packaged chip of a silicon membrane pattern built-in differential piezoresistive pressure sensor is shown in FIG. 4. Reference to the FIGS. 4, 401 is a silicon membrane, 402 is a resistor, and 403 is a passivation layer. 404 is a bonding pad, 405 is a buried cavity, 406 is a vertical channel, 408 is an adhesion layer and 407 is a printed circuit board (PCB). Packaging of the silicon membrane pattern built-in differential piezoresistive pressure sensor does not need an anodic bonded glass base because the sensor chip has an enough mechanical strength to support itself. Anodic bonding can result in a quite large residual stress in a differential piezoresistive pressure sensor. Canceling anodic bonding certainly can greatly improve the performance of the differential piezoresistive pressure sensor greatly.

The silicon membrane pattern buried-in differential piezoresistive pressure sensor shown in FIG. 4 can be fabricated using the above mentioned porous silicon technologies. As an embodiment sample, a method for fabricating the silicon membrane pattern buried-in differential piezoresistive pressure sensor can comprise the steps:
a. providing a porous silicon pattern built-in silicon substrate consisting of a handle silicon layer on the bottom, a porous silicon pattern layer in the middle which has a lot of separated porous silicon layers therein and a silicon epitaxial layer on the top;
b. depositing a passivation layer on the surface of the silicon epitaxial layer;
c. constructing a pressure sensing circuit including a Wheatstone bridge in/on the silicon epitaxial layer on each separated porous silicon layer, several interconnects and several bonding pads on the passivation layer which surround the Wheatstone bridge ;
d. creating a vertical channel reaching the bottom of each separated porous silicon layer by Bosch RIE from the back side of the substrate;
e. removing the separated porous silicon layers by dilute KOH solution etch; and
f. mounting a separated sensor chip directly on a printed circuit board (PCB) without an anodic bonded glass base for additional mechanical strength support.

The handle silicon layer can be made of a (100) p-type silicon substrate with a resistivity of 0.01 to 0.02 Ω-cm. A porous silicon layer in the pattern consists of a top low-porosity layer and a bottom high-porosity layer which are created by anodization in a mixture of 40% HF acid and ethanol at anodic current 5 and 20 mA/cm² respectively using a HF resist mask. The mask materials can be silicon nitride (SiₓN_{y}), Silicon carbide (SiC) or fluoropolymer (FP). The thickness of the low-porosity layer is less 0.5 μm. The total thickness of the porous silicon layer is set to be in the range of 5 to 20 μm which is much less than the thickness of a 6-inch silicon substrate. The shape of patterned porous silicon layer is preferred to be square with a length in the range of 500 μm to 700 μm.

The silicon epitaxial layer can be grown on surface of the handle silicon layer including the surface of a built-in porous silicon pattern through chemical vapor deposition (CVD). Before growing the handle silicon wafer is annealed in a commercial epitaxial reactor at ~1130° C. in 1 atm of dry hydrogen ambient for 10 min. As a result, the pores of the top layer of the porous silicon layer are closed so as to form a densified silicon layer as a seed layer for the epitaxial growth. Then an n-type silicon epitaxial layer is grown on the surface of the handle silicon layer and the porous silicon pattern so as to have a resistivity of ~7.5 Ω-cm and a thickness in the range of 3 to 10 μm.

In order to create a pressure sensing circuit on each portion of the silicon epitaxial layer above each separated porous silicon layer a 20 nm thick silicon dioxide layer can be thermal grown on the surface of the epitaxial layer at ~1050° C. which is used as ion implantation screen. An n-type heavy phosphorous ion implantation with energy of 30 keV and a dose of 1×10¹⁶ cm⁻² is carried out to form an n⁺ layer in the top layer of the silicon epitaxial layer. A p-type heavy boron ion implantation with an energy of 30 keV and a dose of 1×10¹⁶ cm⁻² is carried out to form the lead-out structure for Al interconnection. The resistors are created by boron ion implantation at an energy of 30 keV and a dose of 6−7×10¹⁴ cm−2 which results in Rs~200 Ω and the resistors. Each resulted resistor has a width of 10 μm, a total length of 100 μm, and a resistance of 2 kΩ.

Before conducting back side fabrication steps a 1000 nm thick high density PECVD silicon dioxide layer can be deposited on the surface of the substrate to protect the finished pressure sensing circuit during the subsequent fabrication steps.

On the back side of the substrate a vertical channel can be created using Bosch RIE process. The channel is located under the porous silicon layer and the side length is set to be in the range of 50 to 100 μm. The etching can be automatically stopped as the etching reach the bottom the porous silicon layer.

The porous silicon layer can be removed by etching the porous silicon layer using a dilute KOH solution at room temperature. The concentration of the KOH in Isopropyl Alcohol (IPA) can be set to the range of 1 to 2%.

Finally, the high density PECVD silicon dioxide layer can be removed by dry etching to finish the fabrication process.

Having thus described at least one illustrative embodiment of the invention, various alterations, modifications, and improvements will readily occur to those skilled in the art.

Such alterations, modifications, and improvements are intended to be within the Spirit and Scope of the invention. Accordingly, the foregoing description is by way of example only and is not intended as limiting. The invention is limited only as defined in the following claims and the equivalents thereto.

What is claimed is:

1. A silicon membrane pattern buried-in differential piezoresistive pressure sensor comprises:
a silicon membrane pattern built-in silicon substrate transformed from a porous silicon pattern built-in silicon substrate by etching the porous silicon layer in the porous silicon pattern;
a silicon membrane taken from a portion of a silicon epitaxial layer on the porous silicon pattern and released by etching the porous silicon layer buried under the silicon membrane;
a thin cavity under the silicon membrane and formed also by etching the same porous silicon layer;
a thin vertical channel connecting the thin cavity to the outside of the back side of the substrate and created by Bosch RIE process;
a pressure sensing circuit including a Wheatstone bridge constructed in/on the silicon membrane and several wire bonding pads formed on the surface of the silicon epitaxial layer which surrounds the silicon membrane; and
a printed circuit board (PCB) directly mounting a sensor chip thereon without an anodic bonded glass base for additional sensor chip mechanical support.

2. The silicon membrane pattern buried-in differential piezoresistive pressure sensor of claim 1, wherein said porous silicon pattern built-in silicon substrate consists of a bottom handle silicon layer, a middle porous silicon pattern layer with a lot of separated porous silicon layers therein, and a top silicon epitaxial layer.

3. The silicon membrane pattern buried-in differential piezoresistive pressure sensor of claim 1 wherein the appearance of the silicon membrane in the silicon membrane pattern copied from the appearance of a separated porous silicon layer in the porous silicon pattern and the silicon membrane has a shape and a size as a separated porous silicon layer to have.

4. The silicon membrane pattern buried-in differential piezoresistive pressure sensor of claim 1 wherein said the appearance of the thin cavity copied from the appearance of a separated porous silicon layer in the porous silicon pattern and the thin cavity has a lateral length and a vertical thickness as a separated porous silicon layer to have.

5. The silicon membrane pattern buried-in differential piezoresistive pressure sensor of claim 1, wherein said thin vertical channel is created by Bosch Process (Deep Reactive Ion Etching) using porous silicon as etching stopper so as to allow the created channel stopped at the bottom of a separated porous silicon layer.

6. The silicon membrane pattern buried-in differential piezoresistive pressure sensor of claim 1, wherein said etching the porous silicon layer using diluted KOH solution so as to prevent the silicon epitaxial layer on the top of the porous silicon layer from thickness reducing.

7. The silicon membrane pattern buried-in differential piezoresistive pressure sensor of claim 1, wherein said thin cavity has a thickness in the range of 5 to 20 μm which is much less than the thickness of the handle silicon layer (600 to 700 μm).

8. The silicon membrane pattern buried-in differential piezoresistive pressure sensor of claim 1, wherein said thin vertical channel has a lateral length in the range of 50 to 100 μm which is much less than the lateral length of a silicon membrane (500 to 700 μm).

9. The silicon membrane pattern buried-in differential piezoresistive pressure sensor of claim 1, wherein said differential piezoresistive pressure sensor has a strong mechanical strength so as to be mounted on a PCB (printed circuit board) without an anodic bonded glass base for additional sensor chip mechanical support.

10. A method for fabricating a silicon membrane pattern buried-in differential piezoresistive pressure sensor comprises steps:
providing a porous silicon pattern built-in silicon substrate with a lot of separated porous silicon layers in the middle layer and a silicon epitaxial layer on the porous silicon pattern layer;
constructing a pressure sensing circuit including a Wheatstone bridge in/on the silicon epitaxial layer which is on each separated porous silicon layer and several wire bonding pads on the silicon epitaxial layer which surround the Wheatstone bridge;
depositing a high density silicon dioxide layer on the whole surface of the silicon epitaxial layer;
creating a lot of thin vertical channels each reaching the bottom of a separated porous silicon layer By Bosch DRIE process from the bake side of the silicon substrate;
releasing the silicon epitaxial layer on each separated porous silicon layers by etching the porous silicon layers using diluted KOH solution so as to form a silicon membrane on each etched porous silicon layer;
removing the high density silicon dioxide layer; and
mounting a separated sensor chip directly on a printed circuit board without an anodic bonded glass base for additional sensor chip mechanical support.

11. The method for fabricating a silicon membrane pattern buried-in differential piezoresistive pressure sensor of claim 10, wherein said porous silicon pattern built-in silicon substrate consists of a bottom handle silicon layer, a porous silicon pattern formed in the handle silicon layer, and a top silicon epitaxial layer grown on the surface of the handle silicon layer including the porous silicon pattern formed in the handle silicon layer.

12. The method for fabricating a silicon membrane pattern buried-in differential piezoresistive pressure sensor of claim 10, wherein the appearance of said silicon membrane pattern copied from the appearance of the porous silicon pattern and each silicon membrane has a shape and a size as a separated porous silicon layer to have.

13. The method for fabricating a silicon membrane pattern buried-in differential piezoresistive pressure sensor of claim 10, wherein each said thin cavity is formed by etching a separated porous silicon layer and has a lateral length and a vertical thickness as a separated porous silicon layer to have.

14. The method for fabricating a silicon membrane pattern buried-in differential piezoresistive pressure sensor of claim 10, wherein each said vertical channel is created by Bosch Process (Deep Reactive Ion Etching) using porous silicon as etching stopper so as to allow each created vertical channel stopped at the bottom of a separated porous silicon layer.

15. The method for fabricating a silicon membrane pattern buried-in differential piezoresistive pressure sensor of claim 10, wherein said etching the porous silicon layers using diluted KOH solution so as to prevent the silicon epitaxial layer on the top of the porous silicon layers from thickness reducing.

16. The method for fabricating a silicon membrane pattern buried-in differential piezoresistive pressure sensor of claim 10, wherein each said thin cavity has a thickness in the range of 5 to 20 μm which is much less than the thickness of the handle silicon layer (600 to 700 μm).

17. The method for fabricating a silicon membrane pattern buried-in differential piezoresistive pressure sensor of claim 10, wherein each said vertical channel has a lateral length in the range of 50 to 100 μm which is much less than the lateral length of the silicon membrane (500 to 700 μm).

18. The method for fabricating a silicon membrane pattern buried-in differential piezoresistive pressure sensor of claim 10, wherein the chip of said pressure sensor has a strong mechanical strength so as to be directly mounted on a printed circuit board (PCB) without a anodic bonded glass base for an additional sensor chip mechanical support.

19. The method for fabricating a silicon membrane pattern buried-in differential piezoresistive pressure sensor of claim 13, wherein each said thin cavity has a thickness in the range of 5 to 20 μm which is much less than the thickness of the handle silicon layer (600 to 700 μm).

20. The method for fabricating a silicon membrane pattern buried-in differential piezoresistive pressure sensor of claim 14, wherein each said vertical channel has a lateral length in the range of 50 to 100 μm which is much less than the lateral length of the silicon membrane (500 to 700 μm).
